(19) United States
(12) Patent Application Publication
(10) Pub. No.: US 2004/0017673 A1
(43) Pub. Date: Jan. 29, 2004

(54) Peripheral device packages

(76) Inventor: Michael C. Chao, San Jose, CA (US)

Correspondence Address: BLANK ROME LLP, 600 NEW HAMPSHIRE AVENUE, N.W., WASHINGTON, DC, 20037, US

(21) Appl. No.: 10/200,949

(22) Filed: Jul. 24, 2002

(51) Int. Cl. H05K 7/14; H05K 7/18

(52) U.S. Cl. 361/800

(57) ABSTRACT

The present invention relates to packages for peripheral devices such as memory media and input/output (I/O) devices. The package comprises a top cover and a bottom cover secured to a frame. The covers are secured to the frame through a locking mechanism wherein hooks on the covers lock with and conform around latches on the frame. Methods of making and assembling the package are also disclosed.

### BACKGROUND OF THE INVENTION

1. Field of the Invention

The present invention relates to packages for peripheral devices such as memory media and input/output (I/O) devices. Typically the package holds a printed circuit board (PCB), where the device conforms to standards set by Personal Computer Memory Card International Association (PCMCIA), Japan Electronic Industry Development Association (JEIDA), International Organization for Standardization (ISO), etc. for peripheral devices.

2. Description of Prior Art

The current trend in the computing hardware, telecommunications and electronics industries is to miniaturize components and devices and to place as many of the components and devices next to each other so as to provide quality technical performance in a small package. In order to expand a portable, laptop, or any other type of computer's capacity and functioning capability, manufacturers have devised “plug-in” peripheral cards in the form of printed circuit boards (PCB's) contained within an exterior package. These devices are termed “PCMCIA style peripheral devices”. Such packages have typically been formed from steel with plastic molded frames. However, such packages do not provide a rigid, robust, and precise datum surface upon which a precision assembly may be manufactured.

Certain Personal Computer (PC) card, compact flash or small form factor cards are needed that provide a rigid, accurate structure support for applications such as mini disk drives. The current steel covers with plastic molded frames do not provide enough torsional resistance to external forces, for instance, for such precision PC card applications, liquid crystal diode (LCD) displays, hinges, security devices, personal digital assistants (PDA), digitization of analog information scanners, internet connections, and other wireless communication applications. Also, traditional molding methods result in too much shrinkage, thus forming surfaces not having accurate dimensions. Therefore, it is desired to provide the manufacture of components such as PC cards using materials and compounds that may provide an accurate datum plane due to accurately manufactured parts that are stiff and strong.

Prior art PCMCIA cards typically have two sheet metal covers that are joined together by a plastic frame molded around each cover, as disclosed in U.S. Pat. Nos. 5,397,857 and 5,475,919, the disclosures of which are hereby incorporated by reference. The plastic frames are welded together using ultrasonic welding or resistance welding. The electrically conductive, sheet metal of the top and bottom covers provide a shielding effect against the transmission of electromagnetic radiation through the top and bottom covers. A drawback of the this system is that the ultrasonic welding process may result in damage to components on the PCB due to ultrasonic energy transfer to the PCB if not properly designed.

Other prior art packages employ a “snap together” approach such as U.S. Pat. Nos. 5,505,628; 5,510,959; and 5,574,628, the disclosures of which are also hereby incorporated by reference. This approach employs the use of covers that have mechanical overlaps which attach one cover to the other cover at discrete intervals along the side edge of the package. The mechanical overlaps electrically ground the two covers to each other. The mechanical overlaps traverse or cross over the side edge of the package, as such, only intermittent shielding is provided, which not acceptable. Such solutions, however, add to the size, complexity, material cost, and labor cost of the package. Further, the “snap together” approach does not offer a tight lock that provides rigidity and overall strength.

Therefore, there is a need for a simple to manufacture, assemble package that has high strength and minimizes deleterious effects on the PCB.

### SUMMARY OF THE INVENTION

An object of the present invention is to provide a package for peripheral devices. The package comprises a top cover and a bottom cover secured to a frame. The covers are secured to the frame through a locking mechanism wherein hooks on the covers lock with and conform around latches on the frame. The covers and the frame, when assembled, are capable of encapsulating a PCB and affixing it in proper position.

A further object of the present invention is to provide methods of making a package for peripheral devices. The package has a locking mechanism that is held together with friction that is stronger than prior art packages and requires no welding.

The advantages of the present invention are numerous. Because the molding of the frame and the stamping of the covers are independent steps, the manufacturing time are reduced, thereby lowering manufacturing cost. The process of stamping and molding are well known and well define; therefore, changes to the extended design requires only minimal additional tooling. The multiple locks and tight tolerances result in high rigidity and enclosure strength which are stronger, faster to assemble and more reliable than bonded or “snap together packages.” The mechanical locks do not require ultrasonic welding that can damage components on the PCB. And lastly, the assembly process can be fully automated because of the simplicity and well defined nature of the process.

### BRIEF DESCRIPTION OF THE DRAWINGS

The foregoing background and summary, as well as the following detailed description of the drawings, will be better understood when read in conjunction with the appended drawings. For the purpose of illustrating the invention, there is shown in the drawings embodiments which are presently preferred. It should be understood, however, that the invention is not limited to the precise arrangements and instrumentalities shown. In the drawings:

FIG. 1 shows the top view of the bottom cover.

FIG. 2 shows the side view of the bottom cover.

FIG. 3 shows the cross-section A-A of the bottom cover.

FIG. 4 shows the cross-section B-B of the bottom cover.

FIG. 5 shows the back view of the bottom cover taken from direction X in FIG. 1.

FIG. 6 shows the top view of the top cover.

FIG. 7 shows the side view of the top cover.

FIG. 8 shows the cross-section C-C of the top cover.

FIG. 9 shows the cross-section D-D of the top cover.

FIG. 10 shows the back view of the bottom cover taken from direction Y in FIG. 6.

FIG. 11 shows the top view of the frame.

FIG. 12 shows the side view of the frame.

FIG. 13 shows the bottom view of the frame.

FIG. 14 shows the back view of the frame taken from direction E in FIG. 11.

FIG. 15 shows the front view of the frame taken from direction F in FIG. 11.

FIG. 16 shows the assembly process for the package.

FIG. 17 shows the assembly parts for PC cards.

FIG. 18 shows the plan view of the assembled package with hidden lines.

FIG. 19 shows the side view of the assembled package with hidden lines.

FIG. 20 shows the bottom view of the assembled package with hidden lines.

FIG. 21 shows the plan view of the assembled package without hidden lines.

FIG. 22 shows the side view of the assembled package without hidden lines.

FIG. 23 shows the bottom view of the assembled package without hidden lines.

FIG. 24 shows the cross-sectional view of the assembled package.

FIG. 25 shows a three-dimensional view of a side portion of the frame.

### DETAILED DESCRIPTION OF THE INVENTION

Throughout the drawings like reference numerals refer to like elements. The terms “top” and “bottom” are used to distinguished between the two covers. The use of the terms does not mean that the package will always be oriented with the “top” cover above the “bottom” cover. Either position of these covers are considered to be within the scope of the invention.

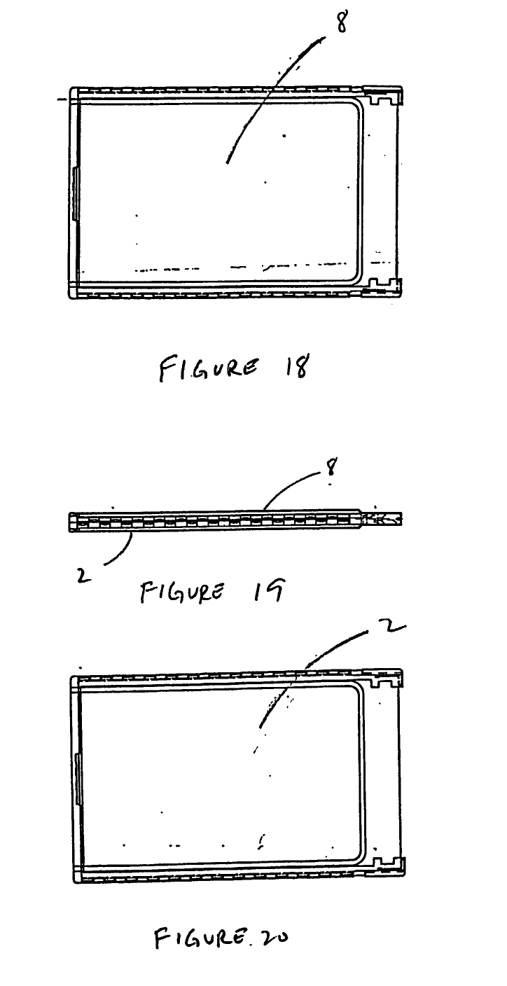

A typical package of the present invention is depicted in FIG. 17. The package comprises a top cover 2, a printed circuit board (PCB) 4, a frame 6, and a bottom cover 8. The top cover 2 and the bottom cover 8 are attached to the frame 6 through a novel locking mechanism to be described later in detail. The package contains and fixes in place a PCB 4.

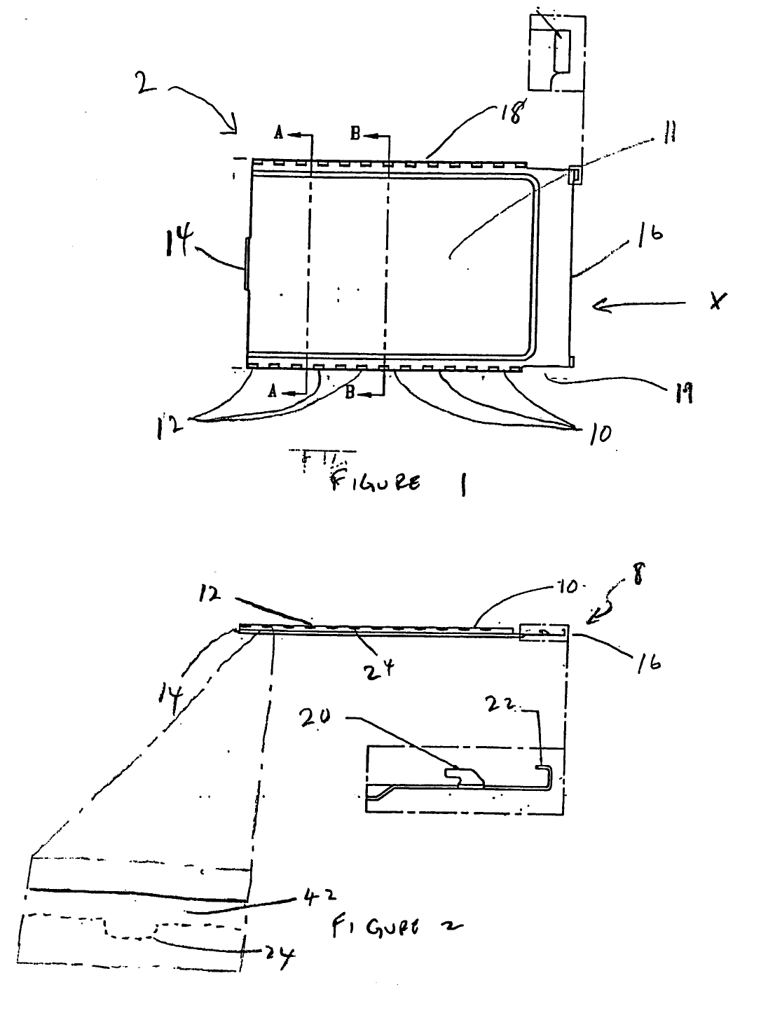

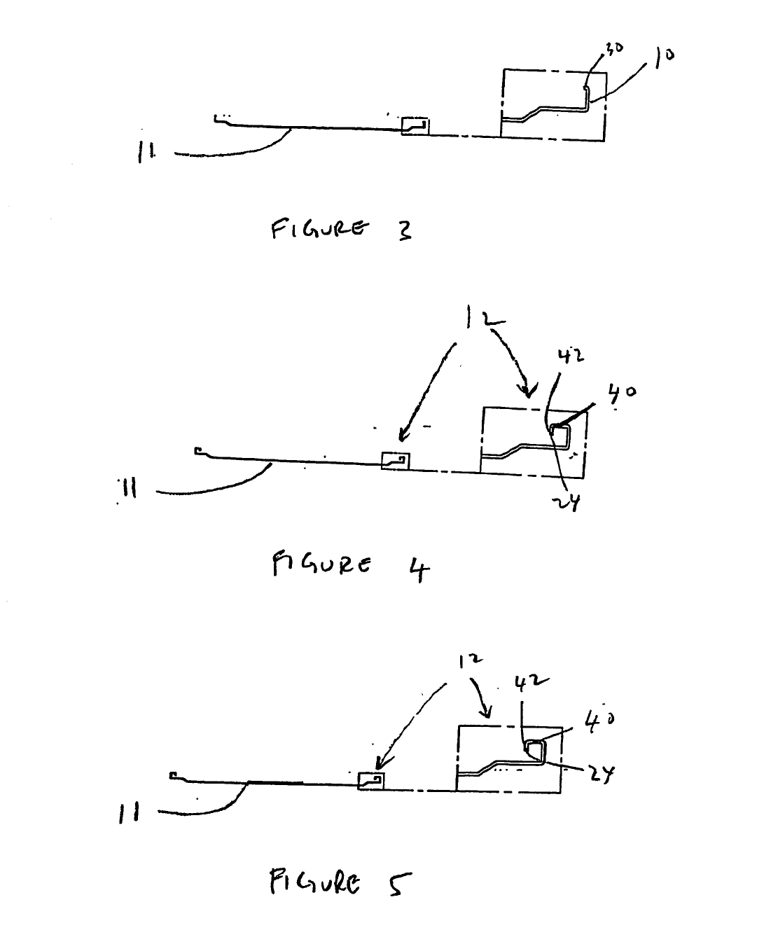

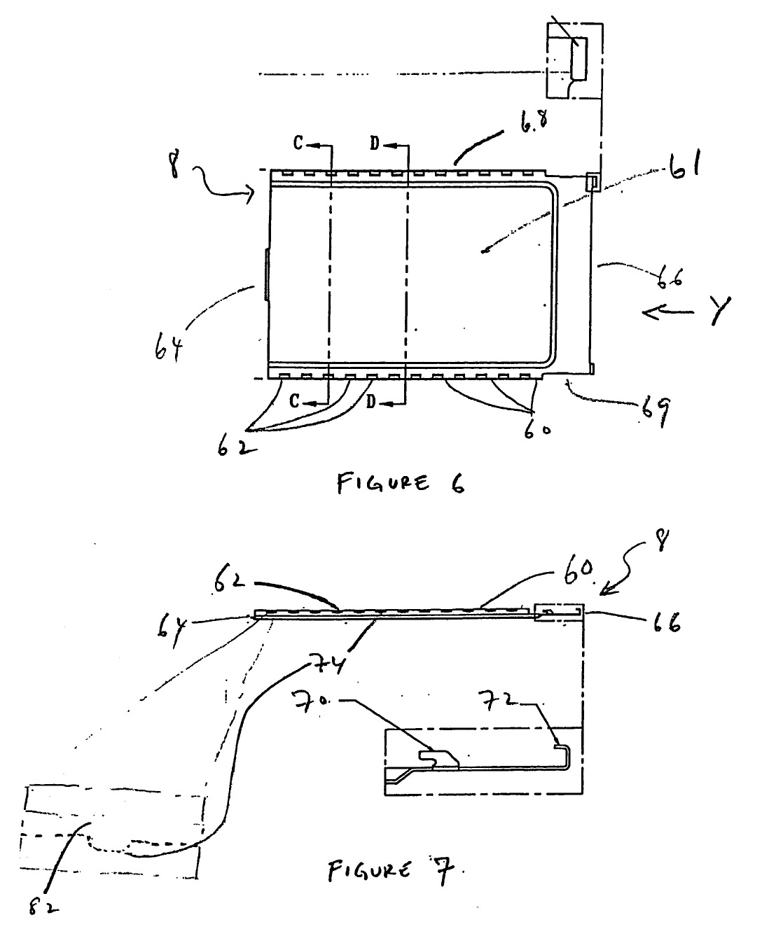

FIGS. 1-5 depict details of the bottom cover 2. The bottom cover 2 is preferably a substantially rectangular piece of metal containing a front side 14, a backside 16, and lateral sides 18 and 19. The surface 11 of the bottom cover is optionally raised in relation to the lateral sides 18 and 19 and the backside 16 in order to accommodate a PCB 4 and other components. The lateral side has alternating hooks 12. The hooks are preferably double folded hooks shown in FIG. 4. The hook comprises a first fold surface 40 and a second fold surface 42. The termination of the second fold surface 42 preferably contains a segmented tab 24 that serves as a guide to precisely position and to lock the bottom cover 2 with the frame 6. The segmented tab 24 is a raise portion at the terminal side of the second fold surface 42 (see FIG. 2). The portion of the lateral sides not containing a hook, referred henceforth as flaps 10, preferably contain a slight bend 30 at the flap termination (FIG. 3). On the lateral sides 18 and 19 are also located hold down tabs 20 towards the backside (see FIG. 2). Friction tab 22 is located at the junction of the lateral sides 18 and 19 and the backside 16.

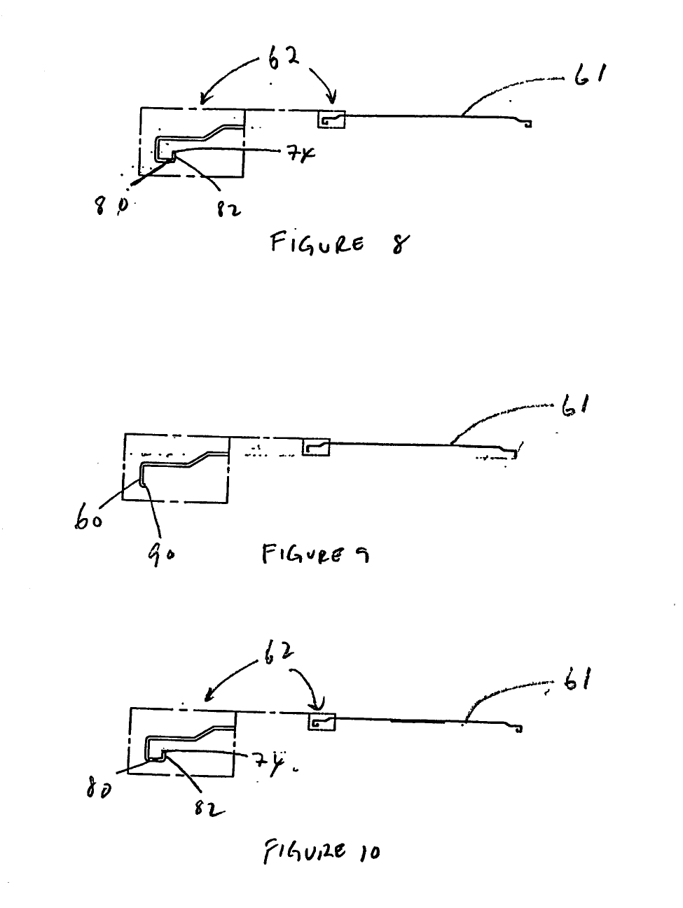

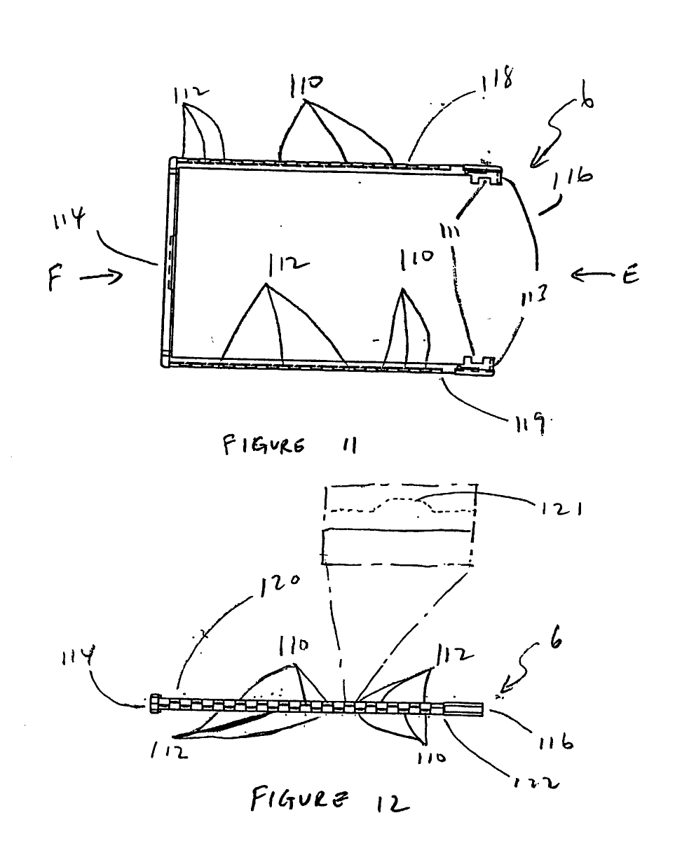

FIGS. 6-10 depict details of the top cover 8. The top cover 8 is substantially identical to the bottom cover 2 with corresponding front side 64, backside 66, and lateral sides 68 and 69. The surface 61 of the bottom cover is optionally raised in relation to the lateral sides 68 and 69 and the backside 66 in order to accommodate a PCB 4 other components. The lateral sides 68 and 69 containing alternating hooks 62 and flaps 60. The location of the hooks 62 and flaps 60 of the top cover 8 are opposite to the location of hooks 12 and flaps 10 on of the bottom cover 2. The positions are shown in FIGS. 1 and 6 where the cross-section C-C of the top cover 8 is at the same position as the cross-section A-A of the bottom cover 2. The cross-section C-C contains hooks (see FIG. 8) while the cross-section A-A contains flaps (see FIG. 3). Also, the hooks 62 of the top cover are preferably double folded hooks with segmented tabs 74. The hook comprises a first fold surface 80 and a second fold surface 82. The segmented tabs 74 are raised portion and the terminal of the second fold surface 82 (see FIG. 7). The flaps 60 of the top cover preferably contain a slight bend 90 at the flap termination (FIG. 9). Correspondingly, the top cover 8 also contains a hold down tab 70 and friction tab 72 locating at the same position as those of the bottom cover 2 as shown in FIG. 7.

Both the top cover 8 and the bottom cover 2 may be constructed of stamped metal such as aluminum or stainless steel. Stamping provides lower manufacturing cost than forged or die cast parts; and metal is preferable in order to provide strength and conductivity for shielding of the PCB 4.

While the material for the covers is chosen to be stamped metal, there is no requirement that it be so. Any rigid material will suffice. However, if the cover is of a conductive material, it will serve to reduce EMI, RF and ESD problems, these being factors which electronic devices seek to minimize. It should be further noted that conductive material cannot be eliminated completely as PCMCIA requires a grounding point. The covers 2 and 8 are generally mirror images of each other, but may not be in certain applications.

An optional addition to the present invention is to coat the interior of the covers 2 and 8 with a thin layer of a non-conductive material. This allows the finished product to have a conductive exterior with a non-conductive interior, thus isolating the conductivity of the interior of the package. Shielding can also be achieved by metallyzed, metal-plated, or conductive plastic material.

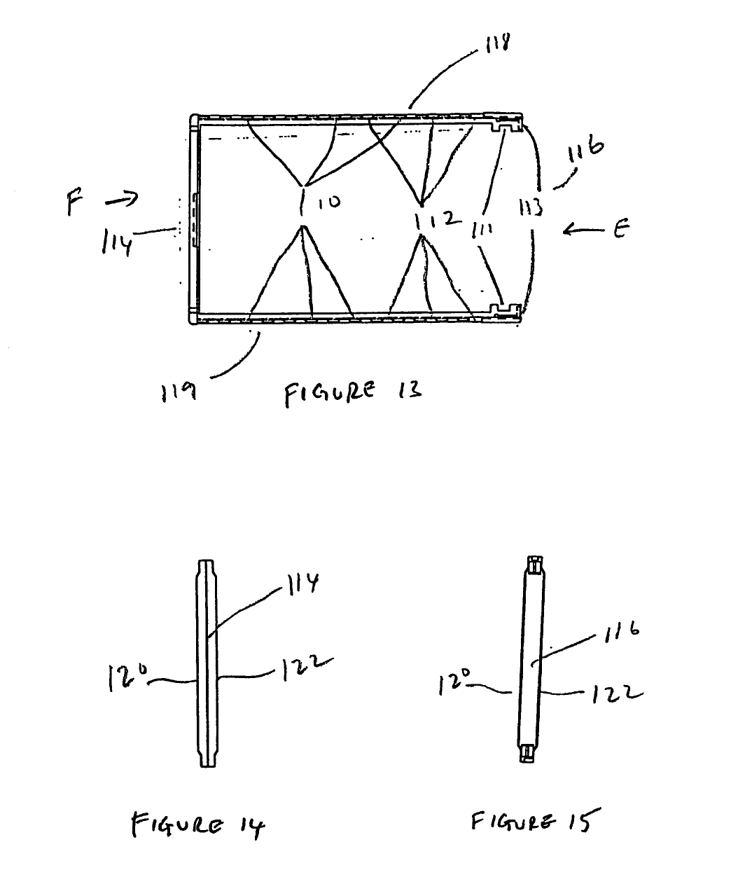

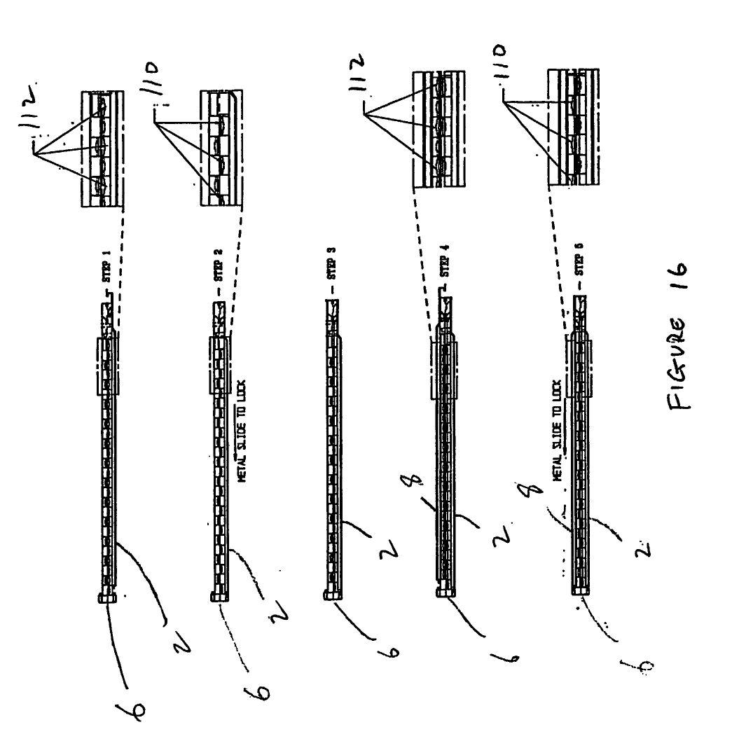

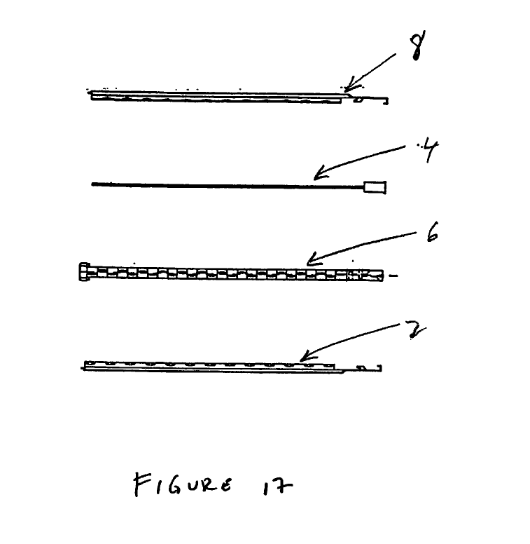

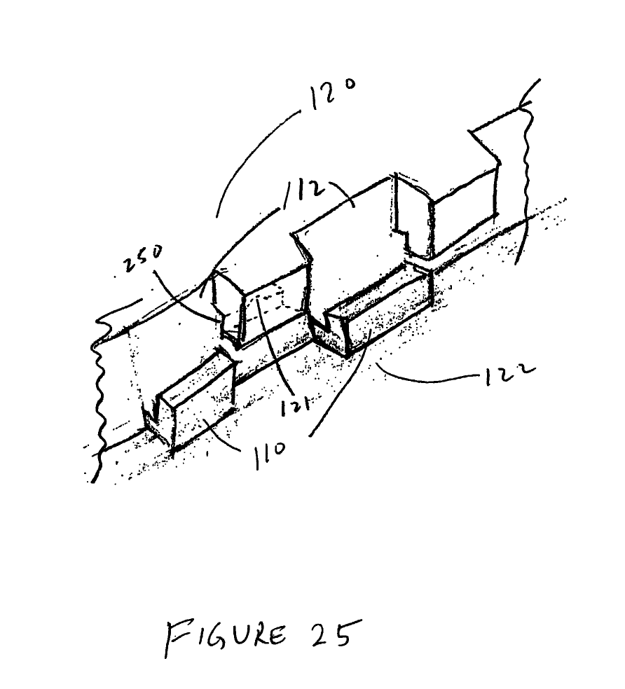

FIGS. 11-15 and 25 depict details of the frame 6. The frame 6 is substantially U-shaped and comprises a front side 114, a backside 116, lateral sides 118 and 119, topside 120, and bottom side 122. The lateral sides have alternating latches 110 and slots 112. The latches 110 are designed to fit with the hooks 12 and 62 of the top and bottom covers 2 and 9. The latches 110 and slots 112 are located on both the topside 120 and the bottom side 122 of the frame 6. Preferably, a topside slot is adjacent to a bottom side latch and vice versa (see FIG. 12). FIG. 25 shows the three-dimensional view of a side (118 or 119) of the frame. The latch is preferably shaped such that a hook (12 or 62) of the top or of the bottom cover conforms to the shape of the latch. The latch preferably has a recess 121 on the inner side 250 (see FIG. 25) that matches the segmented tab (24 or 74) of the hook (12 or 62) to precisely position the hook and to lock it in place. Towards the backside 116, the frame preferably has notches 111 that are capable of engaging the hold down tabs (20 or 70) when the cover is in place. The frame also has cut out slits 113 on the backside 116 to engage the friction tabs 22 and 72 to hold the cover in place.

The frame 6 in a preferred embodiment is constructed of any plastic material such as polycarbonate, nylon, thermal plastic, or various types of engineered plastics. In other embodiments, conductive polymer can also be used by itself or in conjunction with non-conductive plastic. As a further option, the material of the frame 6 can be a metallic material such as aluminum or stainless steel.

FIG. 16 illustrates the assembly process of the present invention. In step 1, the bottom cover 2 is positioned onto the frame 6 with the hooks 12 inserted inside the slots 112 on the bottom side 122 of the frame 6. In step 2, the bottom cover 2 is slid a short distance along the length of the frame 6 to engage the hooks 12 and the latches 110, the hold down tabs 20 and 70 to the notches 111, and the friction tabs 22 and 72 to the slits 113. In this half assembled position (step 3), the hooks 12 which are shaped to conform to the latches 110 engages the latches and are held in place by friction between the frame 6 and the bottom cover 2. Further, in a preferred embodiment, when the segmented tabs 24 of the hooks 12 snap into and engage the recesses 121 on the back sides 250 of the latches 110, frictional force naturally stops the cover and locks it in place. The assembly of the top cover (steps 4 and 5) is similar to that of the bottom cover. In step 4, the top cover 8 is positioned onto the frame 6 with the hooks 62 inserted inside the slots 112 on the topside 120 of the frame 6. In step 5, the bottom cover 8 is slid a short distance along the length of the frame 6 to engage the hooks 62 to the latches 110 to complete the assembly process. Also, in a preferred embodiment, when the segmented tabs 74 of the hooks 62 snaps into and engaged the recesses 121 of the latches 110, frictional force naturally stops the cover and locks it in place.

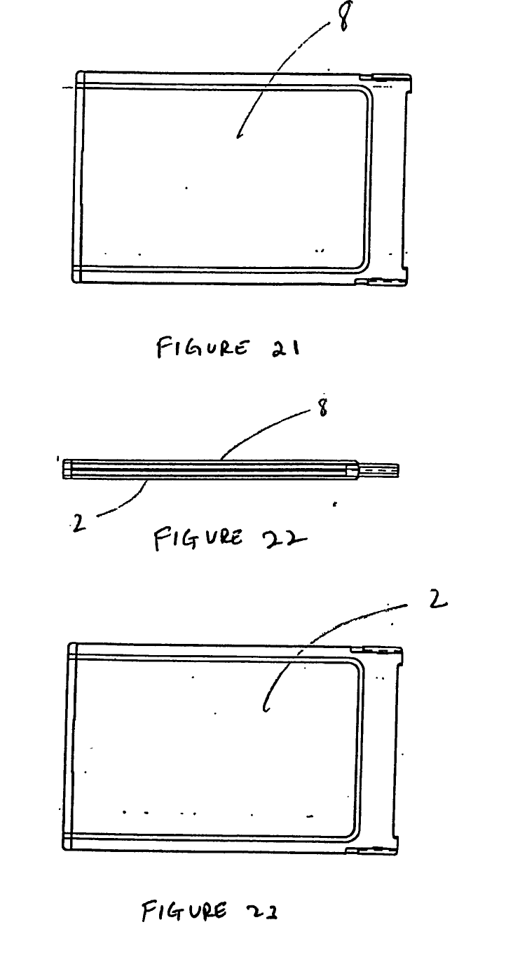

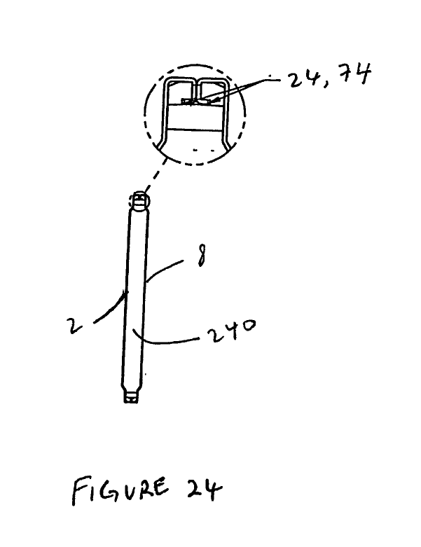

FIGS. 18-24 depict details of the assembled package with (FIGS. 18-20) and without (FIGS. 21-24) hidden lines to clearly show the relationship between the parts of the package. Note that at the back end of the package shown in FIG. 24, there is a gap 240 between the top cover 8 and the bottom cover 2. When a PCB 4 (not shown the FIG. 24) is present, this gap is designed to accommodate a connector, such as a 68-pin connector or other suitable connectors to attach the PCB to a computer or other devices.

Although certain presently preferred embodiments of the invention have been specifically described herein, it will be apparent to those skilled in the art to which the invention pertains that variations and modifications of the various embodiments shown and described herein may be made without departing from the spirit and scope of the invention. Accordingly, it is intended that the invention be limited only to the extent required by the appended claims and the applicable rules of law.

What is claimed is:

1. A peripheral device package comprising:
a top cover having a series of alternating hooks extending from its sides;
a bottom cover having a series of alternating hooks extending from its sides; and
a frame having a series of alternating slots and latches along opposing sides, such that when assembled, the hooks from the top and bottom cover engage the latches on the frame forming a lock to hold the covers in place.

2. The peripheral device package of claim 1, wherein the top and bottom covers are constructed of stamped metallic material.

3. The peripheral device package of claim 2, wherein the stamped metallic material is aluminum or stainless steel.

4. The peripheral device package of claim 1, wherein the top and bottom covers are conductive.

5. The peripheral device package of claim 1, wherein the frame is constructed of metallic material.

6. The peripheral device package of claim 1, wherein the frame is constructed of polymeric material.

7. The peripheral device package of claim 6, wherein the polymeric material is selected from the group consisting of polycarbonate, nylon, and engineered plastic.

8. The peripheral device package of claim 1, wherein the frame is conductive.

9. The peripheral device package of claim 1, wherein the frame is insulative.

10. The peripheral device package of claim 1, wherein the hooks have segmented tabs that fit into recesses in the latches when the hooks engage the latches.

11. A method of making a peripheral device package, said method comprising:
providing a top cover having a series of alternating hooks extending from its sides;
providing a bottom cover having a series of alternating hooks extending from its sides;
providing a frame having a series of alternating slots and latches along opposing sides;
inserting the hooks of the top cover into respective slots in the frame;
sliding the top cover along the length of the frame to engage the hooks and the latches;
inserting the hooks of the bottom cover into respective slots in the frame; and
sliding the bottom cover along a horizontal axis to engage the hooks and the latches.

12. The method of claim 11, wherein the top and bottom covers are constructed of stamped metallic material.

13. The method of claim 12, wherein the stamped metallic material is aluminum or stainless steel.

14. The method of claim 11, wherein the top and bottom covers are conductive.

15. The method of claim 11, wherein the frame is constructed of metallic material.

16. The method of claim 11, wherein the frame is constructed of polymeric material.

17. The method of claim 16, wherein the polymeric material is polycarbonate.

18. The method of claim 11, wherein the frame is conductive.

19. The method of claim 11, wherein the frame is insulative.

20. The method of claim 11, wherein the hooks have segmented tabs that fits into recesses in the latches when the hooks engage the latches.
